(19) United States
(12) Patent Application Publication
(10) Pub. No.: US 2011/0226181 A1
(43) Pub. Date: Sep. 22, 2011

(54) FILM FORMING APPARATUS

(75) Inventor: Kaoru YAMAMOTO, Yamanashi (JP)

(73) Assignee: TOKYO ELECTRON LIMITED, Tokyo (JP)

(21) Appl. No.: 13/045,755

(22) Filed: Mar. 11, 2011

(30) Foreign Application Priority Data
Mar. 16, 2010 (JP) 2010-059964

(51) Int. Cl. C23C 16/448; C23C 16/455; C23C 16/458

(52) U.S. Cl. 118/724

(57) ABSTRACT

Disclosed is a film forming apparatus to form a thin film on a surface of an object to be processed by using a raw material gas including an organometallic compound includes; a processing container to carry out vacuum exhaustion; a placing table having a heater; and a gas introduction mechanism having a plurality of decomposition promoting gas introduction holes facing the placing table, and raw material gas introduction holes, wherein the decomposition promoting gas introduction holes being disposed while facing the object to be processed on the placing table in order to introduce a decomposition promoting gas to promote decomposition of the raw material gas, and the raw material gas introduction holes being disposed while surrounding a formation area of the plurality of decomposition promoting gas introduction holes in order to introduce the raw material gas.

This application is based on and claims priority from Japanese Patent Application No. 2010-059964, filed on Mar. 16, 2010, with the Japanese Patent Office, the disclosure of which is incorporated herein in its entirety by reference.

### TECHNICAL FIELD

The disclosure relates to a film forming apparatus for forming a thin film on an object to be processed such as a semiconductor wafer by using a raw material gas.

### BACKGROUND

Semiconductor integrated circuit devices have been continuously micro-sized. For example, the diameter of the Cu via plug formed in an interlayer dielectric has been decreased from 65 nm to 45 nm. Also, it is expected that the via plug's diameter will be further decreased to 32 nm or 22 nm in the near future.

As the semiconductor integrated circuit device has been micro-sized as described above, the film formation of a barrier metallic film or a Cu seed layer in a micro-sized via hole or a micro-sized wiring groove has been conventionally carried out by a Physical Vapor Deposition (PVD) method. However, the PVD method has been problematic in terms of step coverage. Thus, a film forming technology such as a Metal Organic Chemical Vapor Deposition (MOCVD) method or an Atomic Layer Deposition (ALD) method has been researched. Such technologies are carried out at a low temperature that does not cause damage to an interlayer dielectric made of a low-K material, and also can realize a good step coverage.

However, the MOCVD method or the ALD method generally uses, as a raw material, an organometallic compound including a metallic atom bound to an organic group. Thus, impurities may easily remain in a formed film. For this reason, although the film seems to be formed with a good step coverage at first glance, the quality of the film is unstable. For example, in a case where a Cu seed layer is formed on a Ta barrier metallic film according to the MOCVD method, the formed Cu seed layer may easily cause a cohesion. Thus, it is difficult to form the Cu seed layer on the Ta barrier metallic film in such a manner that the Cu seed layer stably covers the Ta barrier metallic film with a uniform film thickness. When an electroplating of a Cu layer is carried out by using a seed layer having such cohesion as an electrode, a potential defect is included in the Cu layer filling a wiring groove or a via hole. This increases the electric resistance, and also causes a problem such as deterioration of an electron migration resistance or a stress migration resistance.

Therefore, a method for directly forming a barrier metallic film or a Cu seed layer on an interlayer dielectric by an MOCVD technology of a metallic film using a metal carbonyl raw material has been recently suggested. The metal carbonyl raw material can be easily decomposed thermally at a relatively low temperature, thereby forming a metallic film. At the same time, CO which is a ligand of the metal carbonyl raw material may not remain in the formed film, but is exhausted to the outside of a film forming reaction system as it is. Thus, it is possible to form a barrier metallic film or a Cu seed layer of a good quality having small amount of impurities. According to this method, it is possible to form a W film as a barrier metallic film by using, for example, W(CO)₆, or to form a Ru film as a Cu seed layer by using, for example, Ru₃(CO)₁₂. See, for example, Japanese Laid-Open Patent Publication Nos. 2002-60944, and 2004-346401.

In this case, since a metal carbonyl raw material has a characteristic of being very easily decomposed at a relatively low temperature, CO gas having an inhibiting action of the decomposition is used as a carrier gas. Also, a raw material gas including the metal carbonyl raw material is supplied from a shower head provided at the ceiling part of a processing container, and is formed as a film on a heated semiconductor wafer, for example, by CVD. Herein, an example of the conventional film forming apparatus will be described with reference to FIG. 9 which is a schematic configuration view illustrating an example of a conventional film forming apparatus. As shown in FIG. 9, a film forming apparatus 10 has a processing container 12 which is exhausted by an exhausting system 11, and includes a placing table 13 configured to support an object to be processed W including a silicon substrate or the like. Also, a gate valve 12G is formed in processing container 12 to load/unload the object to be processed W.

Placing table 13 is embedded with a heater (not shown), and the heater is driven through a driving line 13A, thereby maintaining the object to be processed W at a desired processing temperature. Exhausting system 11 has a configuration in which a to turbomolecular pump 11A and a dry pump 11B are connected in series. A nitrogen gas is supplied to turbomolecular pump 11A via a valve 11b. A variable conductance valve is provided between processing container 12 and turbomolecular pump 11A to uniformly maintain the voltage within processing container 12.

Also, in film forming apparatus 10, since processing container 12 is subjected to a roughing process by dry pump 11B, an exhaust route 11C is provided that by-passes turbomolecular pump 11A. Also, a valve 11c is provided in exhaust route 11C, and a separate valve 11d is provided at the downstream side of turbomolecular pump 11A. A film forming raw material is supplied to processing container 12 via a gas introduction line 14B in a gas phase from a raw material supply system 14 which includes a bubbler 14A.

In the shown example, Ru₃(CO)₁₂, that is, a carbonyl compound of Ru is maintained in bubbler 14A. CO gas is supplied as a carrier gas from a bubbling gas line 14a which includes a mass flow controller (MFC) 14b. Thus, a vaporized Ru₃(CO)₁₂ raw material gas, together with a CO carrier gas from a line 14d which includes a line MFC 14c, is supplied to processing container 12 via gas introduction line 14B and a shower head 14S, as a processing gas including the raw material gas and the CO carrier gas.

Also, a line 14f is provided in raw material supply system 14 to supply an inert gas such as Ar, and line 14f includes valves 14g, 14h, and an MFC 14e. The inert gas is added to the Ru₃(CO)₁₂ raw material gas supplied to processing container 12 via line 14B.

Also, film forming apparatus 10 includes a control device 10A to control processing container 12, exhausting system 11, and raw material supply system 14.

Also, the formation of a Ru film, caused by a decomposition reaction using the Ru₃(CO)₁₂ raw material, is carried out by a chemical formula below.

Ru₃(CO)₁₂→3Ru+12CO

This reaction proceeds to the right side when a partial pressure of CO gas to existing in a film forming reaction system (a processing container) is low. Thus, CO gas is exhausted to the outside of processing container 12 and the reaction is carried out instantly. As a result, the step coverage of the formed film is deteriorated. For this reason, the inside of processing container 12 is set to be under a high-concentration CO gas atmosphere, so as to inhibit an excessive process of the decomposition reaction. See, for example, Japanese Laid-Open Patent Publication No. 2004-346401.

However, as described above, when the shower head is used as a gas supplying mechanism to supply a raw material gas, the film thickness tends to be thick at the center portion of a wafer, and gradually thinner toward the periphery of the wafer. For this reason, the present applicant has suggested a film forming apparatus which can improve a film forming speed, and improve the in-plane uniformity of a film thickness. See, for example, Japanese Laid-Open Patent Publication No. 2009-239104.

In the film forming apparatus described in Japanese Laid-Open Patent Publication No. 2009-239104 mentioned above, in order to improve the in-plane uniformity of a film thickness, a baffle plate is provided to restrain the film forming speed to some extent and improve the in-plane uniformity of the film thickness at the ceiling part of a processing container, instead of a generally used shower head as used in a conventional system. Furthermore, an inner partition wall is provided in such a manner that it can surround a processing space within the processing container. Also, a raw material gas is discharged from a gas discharging hole provided in the circumferential periphery of the baffle plate toward an area further out than the outer peripheral end of an object to be processed W.

Accordingly, the raw material gas is discharged downward from the gas discharging hole in the vertical direction, while most of the raw material gas is flowed downward, and a part of the raw material gas is diffused and flowed toward the center of the processing space, thereby forming a thin film on the surface of the object to be processed. Then, the gas in the processing space is exhausted downward from a gas outlet formed in a ring shape between the lower portion of the inner partition wall and to the periphery portion of a placing table. In this manner, the in-plane uniformity of a film thickness of a thin film formed on the surface of the object to be processed W along with the film forming speed can be improved.

### SUMMARY

According to one embodiment, there is provided a film forming apparatus to form a thin film on a surface of an object to be processed by using a raw material gas including a raw material of an organometallic compound, the film forming apparatus including: a processing container configured to carry out vacuum exhaustion; a placing table having a heater, on which the object to be processed is disposed; and a gas introduction mechansim having a plurality of decomposition promoting gas introduction holes facing the placing table, and raw material gas introduction holes, wherein the decomposition promoting gas introduction holes being disposed while facing the object to be processed on the placing table in order to introduce a decomposition promoting gas to promote decomposition of the raw material gas, and the raw material gas introduction holes being disposed while surrounding a formation area of the plurality of decomposition promoting gas introduction holes in order to introduce the raw material gas.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a schematic diagram illustrating the entire configuration of a film forming apparatus according to the present disclosure.

FIG. 2 is a schematic cross-sectional view illustrating an example of a film forming apparatus according to the present disclosure.

FIG. 3 is a plan view illustrating an example of a lower surface of a gas introduction mechanism used for a film forming apparatus.

FIG. 4 is an enlarged cross-sectional view illustrating a placing table.

FIG. 5 is a schematic diagram illustrating the flow of a raw material gas and a decomposition promoting gas.

FIG. 6 is a graph showing the action of a decomposition promoting gas (Ar).

FIG. 7 is a schematic diagram illustrating a discharge aspect of a gas, a film forming speed, and the in-plane uniformity of a film thickness.

FIG. 8 is a partial cross-sectional view illustrating a modified embodiment 1 of the present disclosure.

FIG. 9 is a schematic configuration view illustrating an example of a conventional film forming apparatus.

### DETAILED DESCRIPTION

In the following detailed description, reference is made to the accompanying drawings, which form a part thereof. The illustrative embodiments described in the detailed description, drawings, and claims are not meant to be limiting. Other embodiments may be utilized, and other changes may be made, without departing from the spirit or scope of the subject matter presented here.

The above described film forming apparatus is configured using the baffle plate, and, as a result, a high in-plane uniformity of the film thickness can be sufficiently maintained. However, the film forming speed cannot be sufficiently improved due to insufficient reaction efficiency, thereby requiring further improvement. The present disclosure has been made in consideration of these problems so as to effectively solve them, and provides a film forming apparatus which can improve in-plane uniformity of a film thickness, and also increase a film forming speed by improving the reaction efficiency.

In this manner, the film forming apparatus to form a thin film on a surface of an object to be processed by using a raw material gas including a raw material of an organometallic compound includes: a processing container configured to carry out a vacuum exhaustion; a placing table having a heater, on which the object to be processed is disposed; and a gas introduction mechanism having a plurality of decomposition promoting gas introduction holes facing the placing table, and raw material gas introduction holes, wherein the decomposition promoting gas introduction holes being disposed while facing the object to be processed on the placing table in order to introduce a decomposition promoting gas to promote decomposition of the raw material gas, and the raw material gas introduction holes being disposed while surrounding a formation area of the plurality of decomposition promoting gas introduction holes in order to introduce the raw material gas. In the apparatus, from decomposition promoting gas introduction holes, a decomposition promoting gas is flowed, and also from raw material gas introduction holes, a raw material gas is flowed. Thus, it is possible to improve in-plane uniformity of a film thickness, and also to increase a film forming speed by improving reaction efficiency.

In the film forming apparatus, the decomposition promoting gas introduction holes may be disposed at a position corresponding to the upper side of the object to be processed in a perpendicular direction on the placing table, and the raw material gas introduction holes may be disposed at a position corresponding to the upper side of an area further out than an outer peripheral end of the object to be processed in a perpendicular direction on the placing table.

In the film forming apparatus, the processing container may have an inner partition wall within the processing container, wherein the inner partition wall partitions a processing space at an upper side of the placing table in such a manner that the inner partition wall surrounds the processing space, a lower end portion of the inner partition wall is provided in such a manner that the lower end portion approaches the placing table, and a gas outlet is formed between the lower portion and a circumferential periphery of the placing table.

In the film forming apparatus, an orifice forming member may be provided at the lower end portion of the inner partition wall extending toward an inner side along a radial direction of the placing table, and an orifice communicating with the gas outlet is formed between the orifice forming member and the circumferential periphery of the placing table.

In the film forming apparatus, the inner partition wall and the orifice forming member may be maintained at a temperature range of lower than a decomposition temperature of the raw material gas, and a temperature range equal to or higher than a solidifying temperature or a liquidizing temperature of the raw material gas.

In the film forming apparatus, the placing table may be configured to be moved up and down.

In the film forming apparatus, the organometallic compound may include one material selected from the group consisting Ru₃(CO)₁₂, W(CO)₆, Ni(CO)₄, Mo(CO)₆, CO₂(CO)₈, Rh₄(CO)₁₂, Re₂(CO)₁₀, Cr(CO)₆, Os₃(CO)₁₂, Ta(CO)₅, tetrakis(ethylmethylamino)titanium (TEMAT), TAIMATA, Cu(EDMDD)₂, TaCl₅, trimethyl aluminum (TMA), tertiary-butylimide-tridiethylamide tantalum (TBTDET), pentaethoxy tantalum (PET), tetramethylsilane (TMS), tetrakisethoxy hafnium (TEH), Cp₂Mn[═Mn(C₅H₅)₂], (MeCp)₂Mn[=Mn(CH₃C₅H₄)₂], (EtCp)₂Mn[═Mn(C₂H₅C₅H₄)₂], (i-PrCp)₂Mn[=Mn(C₃H₇C₅H₄)₂], MeCpMn(CO)₃[═(CH₃C₅H₄)Mn(CO)₃], (t-BuCp)₂Mn[=Mn(C₄H₉C₅H₄)₂], CH₃Mn(CO)₅, Mn(DPM)₃[═Mn(C₁₁H₁₉O₂)₃], Mn(DMPD)(EtCp)[=Mn(C₇H₁₁C₂H₅C₅H₄)], Mn(acac)₂[=Mn(C₅H₇O₂)₂], Mn(DPM)₂[=Mn(C₁₁H₁₉O₂)₂], and Mn(acac)₃[=Mn(C₅H₇O₂)₃].

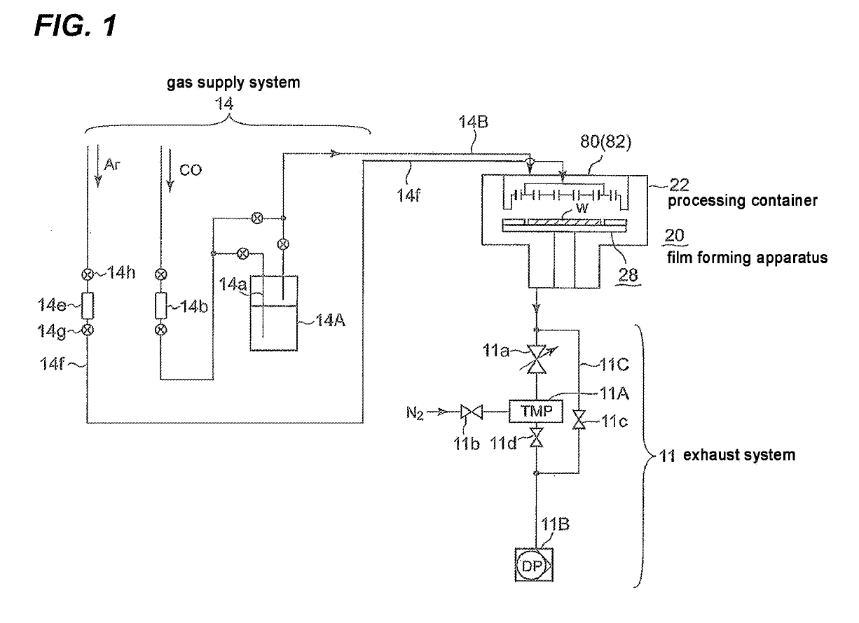

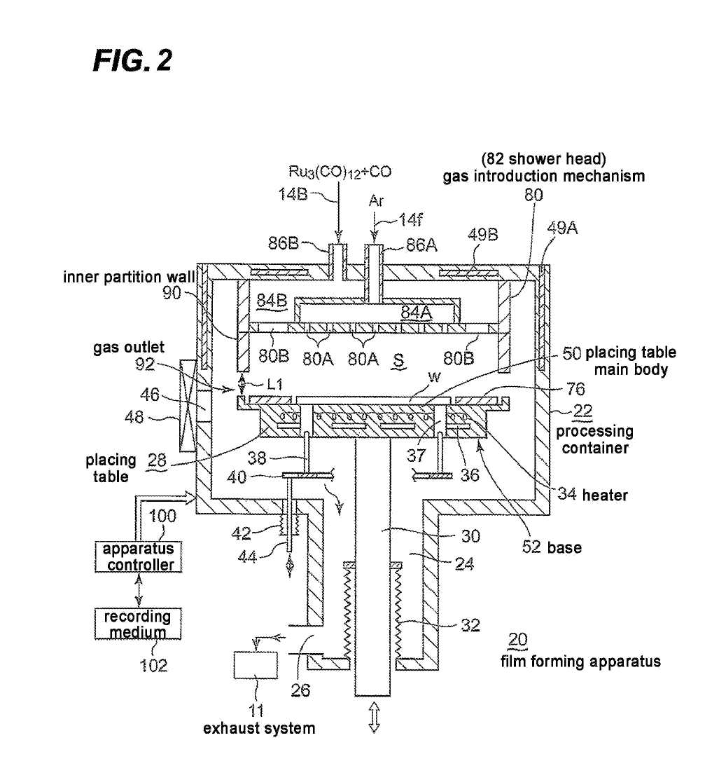

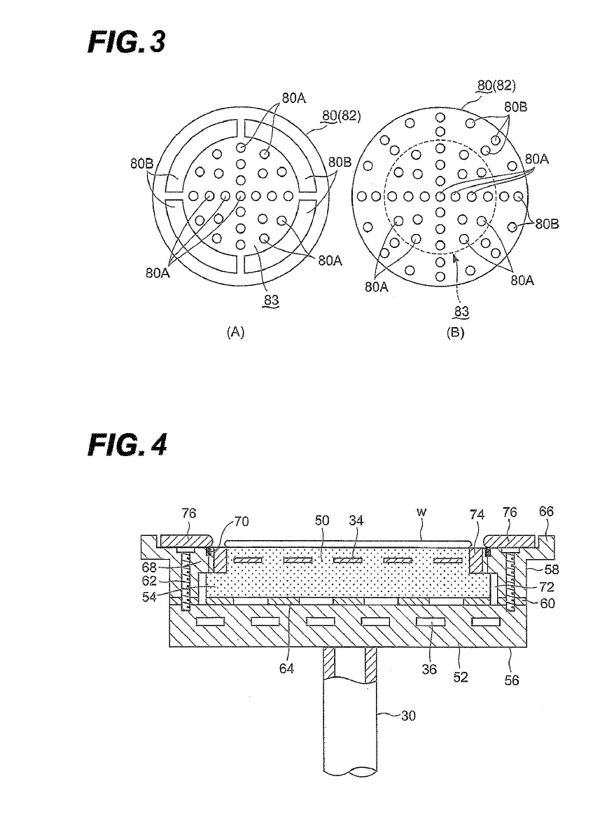

Hereinafter, a film forming apparatus according to one embodiment of to the present disclosure will be described in detail with reference to the accompanying drawings. FIG. 1 is a schematic configuration view illustrating the entire configuration of a film forming apparatus according to the present disclosure, FIG. 2 is a schematic cross-sectional view illustrating an example of a film forming apparatus according to the present disclosure, FIG. 3 is a plan view illustrating an example of a lower surface of a gas introduction mechanism used for a film forming apparatus, and FIG. 4 is an enlarged cross-sectional view illustrating a placing table.

First, the entire processing system including a gas supply system or an exhaust system which is connected to the film forming apparatus will be described. As shown in FIG. 1, a film forming apparatus 20 has a processing container 22 configured to receive a semiconductor wafer W including, for example, a silicon substrate, as an object to be processed. In order to exhaust the atmosphere in processing container 22, an exhaust system 11 is connected to processing container 22. Exhaust system 11 has a configuration in which a turbomolecular pump 11A and a dry pump 11B are connected in series. Nitrogen gas is supplied to turbomolecular pump 11A via a valve 11b. A variable conductance valve 11a is provided between processing container 22 and turbomolecular pump 11A to uniformly maintain a voltage within processing container 22.

Also, in film forming apparatus 20, since processing container 22 is subjected to a roughing process by dry pump 11B, an exhaust route 11C by-passing turbomolecular pump 11A is provided. Also, a valve 11c is provided in exhaust route 11C, and a separate valve 11d is provided at the downstream side of turbomolecular pump 11A. Also, a trap device (not shown) is provided at the downstream side of dry pump 11B to remove residue from the exhausted gas.

A gas supply system 14 is connected to processing container 22 to supply various gases such as a raw material gas. A bubbler 14A is provided in gas supply system 14, and thus a film forming raw material is supplied in a gas phase via a gas introduction line 14B. A raw material received in bubbler 14A may be in a liquid phase or in a gas phase according to the kind of the raw material.

In the shown example, Ru₃(CO)₁₂, that is, a carbonyl compound of Ru is kept in bubbler 14A as a raw material, and CO gas is supplied as a carrier gas from a bubbling gas line 14a including a mass flow controller (MFC) 14b. Thus, a vaporized Ru₃(CO)₁₂ raw material gas is introduced into processing container 22 via gas introduction line 14B.

Also, a gas introduction line 14f including valves 14g, 14h and an MFC 14e is provided in gas supply system 14 to supply an inert gas such as Ar. As a result, the inert gas may be supplied to processing container 22 as required.

Hereinafter, with reference to FIG. 2, film forming apparatus 20 according to the present disclosure will be described. As described above, film forming apparatus 20 has body-structured processing container 22 made of, for example, an aluminum alloy. Processing container 22 includes an upper chamber having a large inner diameter, and a lower chamber having an inner diameter smaller than that of the upper chamber. The inside of the lower chamber is formed as an exhaust space 24. An exhaust port 26 is formed in a lower side wall partitioning exhaust space 24 as the lower chamber. Exhaust system 11 is connected to exhaust port 26. A placing table 28 is provided within processing container 22 on which a semiconductor wafer W is disposed as an object to be processed.

Placing table 28 is molded in, for example, a disc shape as a whole, and has a diameter larger than that of semiconductor wafer W. Semiconductor wafer W is disposed on the upper surface of placing table 28. Also, placing table 28 is attached to and fixed on the upper end portion of a metallic pillar 30 made of, for example, an aluminum alloy. Pillar 30 stands up at a position higher than the bottom portion side of processing container 22. Also, pillar 30 extends downward by penetrating the bottom portion partitioning exhaust space 24, and is configured to stop the entire placing table 28 at any position by moving up and down the placing table by an actuator (not shown). Also, a flexible metallic bellows 32 is provided at the bottom portion of the container, maintaining airtightness within processing container 22 while allowing placing table 28 to be moved up and down.

A heater 34 including, for example, a tungsten wire heater, a carbon wire heater or the like, as a heating mechanism, is embedded at the upper portion of placing table 28 so as to heat semiconductor wafer W. At the lower side of heater 34, a refrigerant passage 36 is provided which allows a refrigerant (such as a cooling water) to flow, thereby adjusting a temperature by cooling the lower portion or the lateral portion of placing table 28. Placing table 28 will be described in detail later. Also, in the periphery portion of placing table 28, a plurality of, for example, three (3) (only two (2) are shown in the shown example) pin insertion through-holes 37 are provided. A lifter pin 38 can be inserted and penetrated within each of pin insertion through holes 37.

Also, the lower portion of each lifter pin 38 is supported by an elevating arm 40 which is elevatable by an elevating rod 44. Elevating rod 44 airtightly penetrates a bottom portion of a container by a bellows 42. Also, in a state where placing table 28 is lowered to a carrying/loading position of wafer W, lifter pin 38 pops up at the upper portion of placing table 28 so as to push up or down wafer W. Also, an opening 46 is formed at a position where placing table 28 is lowered, in the side wall of the container corresponding to the horizontal level of the upper surface of placing table 28. Semiconductor wafer W is loaded and unloaded by a carrying arm (not shown) through opening 46. Also, a gate valve 48 is provided in opening 46 so as to airtightly open/close opening 46.

Also, heaters 49A and 49B are provided in a side wall and a ceiling portion of processing container 22, respectively. Heaters 49A and 49B maintain the lateral wall and the ceiling part at a predetermined temperature so as to prevent a raw material gas from being solidified or liquidized.

Also, placing table 28 mainly includes a placing table main body 50 and a base 52. Placing table main body 50 allows semiconductor wafer W to be disposed thereon, and includes heater 34 therewithin. Base 52 supports placing table main body 50 in a state where the placing table surrounds the lateral surface and the bottom surface of placing table main body 50 through interposition of a heat-insulating layer (not shown). Also, refrigerant passage 36 allowing a refrigerant to flow is provided within base 52 so that base 52 is maintained at a temperature range of lower than a decomposition temperature of a raw material gas, and a temperature range equal to or higher than a solidifying temperature or a liquidizing temperature of the raw material gas. Also, in FIG. 4, the description on pin insertion through-holes 37 and lifter pin 38 is omitted for brevity.

The entire placing table main body 50 is molded in a disc shape by a ceramic material, a metal or the like, and heater 34 is embedded therewithin, as a heating mechanism, in an insulated state over approximately the entire surface. Heater 34 includes a tungsten wire, a carbon wire, or the like. A temperature control can be carried out through heater 34 in such a manner that semiconductor wafer W directly disposed on (contacting with) the upper surface of placing table main body 50 can be heated up to a desired temperature.

For example, aluminum nitride (AlN), aluminum oxide (Al₂O₃), silicon carbide (SiC), etc. may be used as the ceramic material, and aluminum, aluminum alloy, etc. may be used as the metal. Also, the diameter of placing table main body 50 is set to be slightly smaller than that of semiconductor wafer W. For example, when the diameter of semiconductor wafer W is 300 mm, the diameter of placing table main body 50 is set as about 295 mm. In the circumferential periphery of placing table main body 50, a stepped portion 54 (see FIG. 4) having a perpendicularly cut-away cross section is formed in a ring shape along the circumferential direction.

Also, base 52 is made of a metal as a whole including a disc-shaped metallic base portion 56, and a ring-shaped metallic edge ring 58. Refrigerant passage 36 is provided within base portion 56 over approximately the entire surface. Edge ring 58 stands up in the circumferential periphery of base portion 56 in such a manner that the edge ring can surround the later surface of placing table main body 50. Cooling water, fluorinert, Galden (registered trade mark), or the like may flow through a pipe (not shown) as a refrigerant.

Between base portion 56 and edge ring 58, a ring-shaped heat-conduction alleviating member 60 is interposed. Heat-conduction alleviating member 60 alleviates the cooling of edge ring 58 and is made of a low heat-conductivity metal. Also, edge ring 58, heat-conduction alleviating member 60, and base portion 56 are integrally combined by a plurality of bolts 62 at the upper side thereof in such a manner that they can be detached (disassembled).

Herein, base portion 56 or edge ring 58 is made of aluminum or aluminum alloy, and heat-conduction alleviating member 60 is made of stainless steel having heat-conductivity lower than that of aluminum or aluminum alloy. Also, heat-conduction alleviating member 60 may be omitted because it can be provided as required. Also, base portion 56 or edge ring 58 may be made of stainless steel instead of aluminum or aluminum alloy, although stainless steel has slightly low heat conductivity.

Also, a heat insulator 64 is interposed between the upper surface of base portion 56 and the bottom portion (lower surface) of placing table main body 50 to support placing table main body 50 and insulate the base portion from the placing table main body. A ceramic material, stainless steel, etc. having a low heat conductivity and a high heat resistance may be used as heat insulator 64.

Also, the upper surface of edge ring 58 is formed with a ring-shaped flange portion 66 having the same level as the horizontal level of the disposition plane of semiconductor wafer W. Herein, flange portion 66 extends by a predetermined length at the outside along the radial direction of semiconductor wafer W.

Also, at the upper portion of the inner periphery side of edge ring 58, a protrusion 68 protruding to semiconductor wafer W's side is provided in a ring shape along the circumferential direction. Protrusion 68 extends to a halfway point of stepped portion 54 of placing table main body 50. Also, fixing screws 70 are provided downwardly in protrusion 68 penetrating the protrusion. Fixing screws 70 presses the periphery portion of placing table main body 50 by moving downward while fixing protrusion 68. Accordingly, the inner circumferential surface of edge ring 58 and the outer circumferential surface of placing table main body 50 do not directly contact with each other, and a space 72 is formed between the edge ring and the placing table main body for a heat insulation. Also, the number of fixing screws 70 is, for example, only about six (6) as a whole, which improves heat insulation between edge ring 58 and placing table main body 50.

Also, a ring-shaped shield ring 74 is detachably provided in a movably fitted state between the lateral surface of stepped portion 54 of placing table main body 50 and the inner circumferential surface of protrusion 68 of edge ring 58 state. Shield ring 74 is made of a metal such as aluminum or aluminum alloy, and has functions of inhibiting film formation on the side wall of placing table main body 50, securing the in-plane uniformity of temperature of semiconductor wafer W, inhibiting film formation on the rear surface of semiconductor wafer W, and heat-insulating placing table main body 50 from edge ring 58.

Also, a ring-shaped cover ring 76 is provided at the upper surface side of edge ring 58 in order to prevent a film from being attached on a bevel portion (as a periphery end portion of semiconductor wafer W). Cover ring 76 is made of a ceramic material such as alumina or aluminum nitride. Similar to edge ring 58, the temperature of cover ring 76 is maintained at a temperature range of lower than a decomposition temperature of a raw material gas, and a temperature range equal to or higher than a solidifying temperature or a liquidizing temperature of the raw material gas, during a film forming process.

Also, in the ceiling part of processing container 22, a gas introduction mechanism 80 is provided in the ceiling part of processing container 22 for introducing required gas, while facing placing table 28. Also, a raw material gas and a decomposition promoting gas for promoting the decomposition of the raw material gas are separately introduced to a processing space S through gas introduction mechanism 80. The raw material gas, as described above, is carried by a carrier gas (CO gas).

In this case, in order to discharge the decomposition promoting gas, a plurality of decomposition promoting gas introduction holes 80A are formed facing wafer W on placing table 28. Also, raw material gas introduction holes 80B for introducing the raw material gas are formed in such a manner that the raw material gas introduction holes can surround the formation area of decomposition promoting gas introduction holes 80A.

Specifically, gas introduction mechanism 80 is formed with a shower head 82 in this exemplary embodiment. As shown in FIG. 3(A), in a center area 83 of a gas spray surface on the lower surface of shower head 82, the plurality of decomposition promoting gas introduction holes 80A are formed. Also, raw material gas introduction holes 80B are formed in such a manner that they can surround the periphery of a formation area 83 of decomposition promoting gas introduction holes 80A. Then, the inside of shower head 82 is divided into two spaces, in which two diffusion chambers 84A and 84B are formed.

Gas introduction ports 86A and 86B are formed in the ceiling part of the container in such a manner that they can communicate with diffusion chambers 84A and 84B, respectively. Also, gas introduction line 14f of gas supply system 14 is connected to one of gas introduction ports 86A so as to supply inert gas including Ar as a decomposition promoting gas. Also, gas introduction line 14B of gas supply system 14 is connected to the other gas introduction port 86B so as to supply a raw material gas accompanied by a carrier gas.

Herein, decomposition promoting gas introduction holes 80A include through holes with a diameter size of about 0.5 to 10 mm. Meanwhile, raw material gas introduction holes 80B are molded in a circular arc shape having a large opening area along the circumferential direction of shower head 82. Also, as described above, decomposition promoting gas introduction holes 80A are dispersed while facing wafer W on placing table 28. Meanwhile, raw material gas introduction holes 80B are positioned at the upper side in a perpendicular direction of an area further out than the outer peripheral end of wafer W on placing table 28, while corresponding to the outer area. In other words, decomposition promoting gas introduction holes 80A are disposed at the upper side in a perpendicular direction of wafer W on placing table 28, while raw material gas introduction holes 80B are disposed at the upper side in a perpendicular direction of an area further out than the outer peripheral end of wafer W on placing table 28.

In this manner, it is possible to prevent a very easily decomposable raw material gas from focusing on the center portion of wafer W, which allows a film formation to be uniformly carried out within the plane of a wafer. Also, it is possible to promote the decomposition of the raw material gas, thereby increasing a film formation speed.

In other words, a position just below raw material gas introduction holes 80B corresponds to an area further out than the outer peripheral end of wafer W, in which the raw material gas is discharged toward the outer area. In this manner, the raw material gas is not directly flowed down on the upper surface of wafer W, but flowed down toward the area further out than the circumferential periphery of wafer W. Thus, it is possible to secure the in-plane uniformity of film thickness on wafer W during film forming process.

Also, raw material gas introduction holes 80B may include a plurality of small-diametric through holes in the same shape as that of the decomposition promoting gas introduction holes 80A, as shown in FIG. 3(B), instead of large openings in a circular arc shape, as shown in FIG. 3(A). Shower head 82 is made of a metal material having a satisfactory heat conductivity, for example, aluminum or aluminum alloy. Herein, a ring-shaped inner partition wall 90 is provided while further extending from a side wall portion of shower head 82 in a lower direction.

Herein, inner partition wall 90 is integrated with shower head 82, and is made of the same material as that of shower head 82. Inner partition wall 90 is provided in such a manner that it can surround the periphery of processing space S at the upper side of placing table 28. Also, the lower portion of inner partition wall 90 approaches placing table 28. Also, a gas outlet 92 for exhaustion is formed between the lower end portion of inner partition wall 90 and the circumferential periphery of placing table 28.

Gas outlet 92 is formed in a ring shape along the circumferential direction of placing table 28. The atmosphere of processing space S is uniformly exhausted from the outer periphery side of wafer W through gas outlet 92. Inner partition wall 90 partitioning gas outlet 92 is positioned at the upper side of flange portion 66 and cover ring 76, positioned at the circumferential periphery of placing table 28. Gas outlet 92 is formed between the upper surface of cover ring 76 (including a part of the upper surface of flange portion 66), and the lower end surface of inner partition wall 90 having a predetermined thickness. A vertical width L1 of gas outlet 92 is set as a value ranging from 2 to 19.5 mm, for example, about 5 mm.

Referring back to FIG. 1, the entire operation of film forming apparatus 20 as configured above, such as the initiation and stop of gas supply, and the control of a process temperature, a process pressure, and a temperature of refrigerant flowing through refrigerant passage 36, is carried out by an apparatus controller 100 including, for example, a computer.

A computer-readable program required for the control is recorded in a recording medium 102. As recording medium 102, a flexible disc, a compact disc (CD), a CD-ROM, a hard disc, a flash memory, a DVD, or the like may be used.

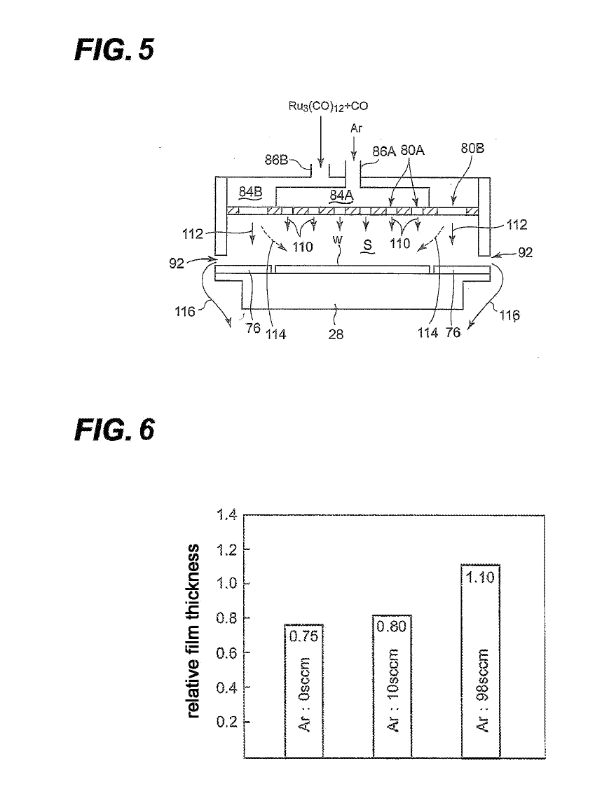

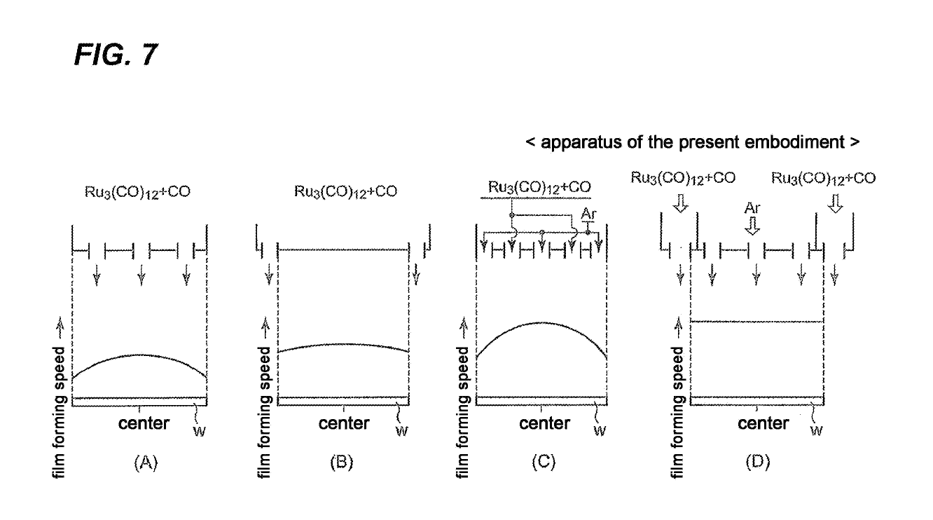

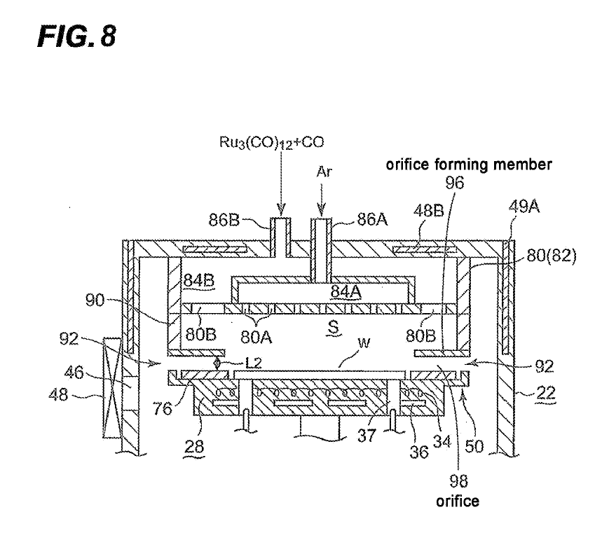

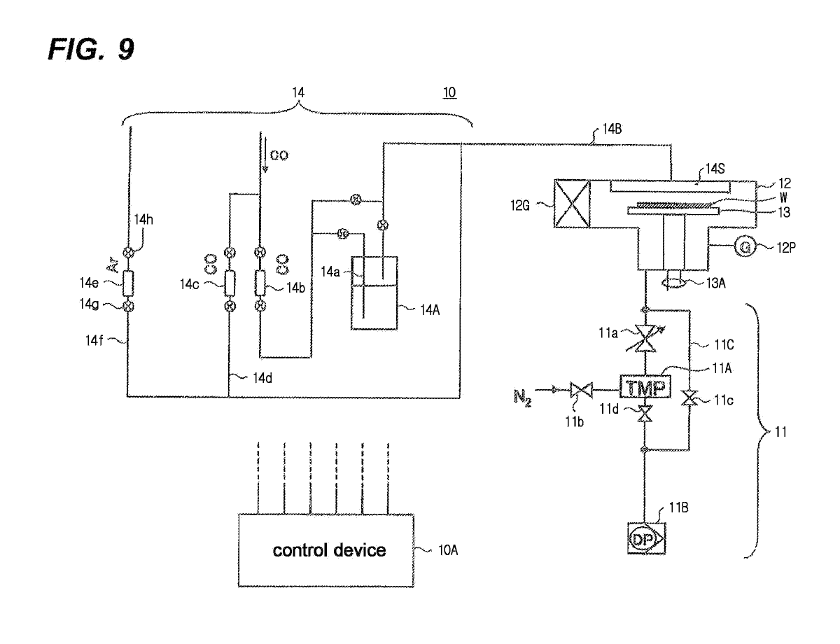

Hereinafter, a film forming processing to be performed by using film forming apparatus 20 as configured above will be described with reference to FIGS. 5 to 7. FIG. 5 is a schematic diagram illustrating the flow of a raw material gas and a decomposition promoting gas, FIG. 6 is a graph showing the action of a decomposition promoting gas (Ar), and FIG. 7 is a schematic diagram illustrating a discharge aspect of a gas, a film forming speed, and the in-plane uniformity of a film thickness. First, as shown in FIG. 1, in film forming apparatus 20, exhaust system 11 is continuously driven, and thus the inside of processing container 22 is maintained at a predetermined pressure in a vacuum state. Also, semiconductor wafer W supported by placing table 28 is maintained at a predetermined temperature by heater 34.

Also, each of the side wall and the ceiling part of processing container 22, shower head 82 constituting gas introduction mechanism 80, and inner partition wall 90 is maintained at a predetermined temperature by heaters 49A and 49B. The temperature is in a range of lower than a decomposition temperature of a raw material gas, and in a range equal to or higher than a solidifying temperature or a liquidizing temperature of the raw material gas. For example, the heated temperature is about 80□. Also, a raw material gas (Ru₃(CO)₁₂) is supplied from gas supply system 14 together with a carrier gas including CO gas. Also, as a decomposition promoting gas, an inert gas, that is, Ar gas, is supplied. These gases are flowed, respectively, into shower head 82 by gas introduction mechanism 80, while being subjected to mass flow control. Ar gas is flowed into one diffusion chamber 84A from gas introduction port 86A, and is discharged toward processing space S from decomposition promoting gas introduction holes 80A through diffusion within the chamber 84A. Also, the raw material gas together with a carrier gas is flowed into another diffusion chamber 84B from gas introduction port 86B, and is discharged toward processing space S from raw material gas introduction holes 80B through diffusion within the chamber 84B.

Herein, as shown in FIG. 5, Ar gas is flowed downward toward the above position of wafer W from the plurality of decomposition promoting gas introduction holes 80A, as indicated by arrows 110. Meanwhile, from raw material gas introduction holes 80B surrounding the outside of decomposition promoting gas introduction holes 80A, the raw material gas is flowed downward toward the outside area of the outer peripheral end of wafer W, as indicated by arrows 112. The downward flowing direction of the raw material gas is toward the outside area of the outer peripheral end of wafer W, as a circumferential periphery of placing table 28. Also, as indicated by arrows 114, a part of the raw material gas is diffused toward the center portion within processing space S, and is maintained, during the flowing-down. Also, the raw material gas is mixed with Ar gas in processing space S, which promotes the decomposition of the raw material gas. Also, a supply aspect of firstly mixing gases in processing space S is referred to as a post mix.

Then, a part of the raw material gas is maintained within processing space S while the decomposition of the raw material gas is promoted by Ar gas. Also, a large amount of raw material gas (including CO gas) together with Ar gas is flowed into a space below placing table 28 via gas outlet 92 with a narrowed path area, as indicated by arrows 116. Then, the atmosphere in the processing container 22 is discharged to the outside of the container via exhaust port 26. Herein, the raw material gas is thermally decomposed in processing space S, while a Ru film as a thin film is formed by a CVD method. Also, at the same time, as described above, the decomposition of the raw material gas is promoted by Ar gas, thereby increasing the film forming speed. The film forming reaction is represented by chemical formulas below, and carbon monoxide (CO), that is, the same kind of gas as a carrier gas, is generated by the reaction.

Ru₃(CO)₁₂□Ru₃(CO)₁₂↑

Ru₃(CO)₁₂↑□Ru₃(CO)₁₂₋ₓ↑+XCO↑

Ru₃(CO)₁₂₋ₓ↑+Q→3Ru+(12−X)CO↑

Ru₃(CO)₁₂↑+Q→3Ru+12CO↑

Herein, “□” indicates reversibility, “↑” indicates a gas state, no “↑” indicates a solid state, and “Q” indicates an addition of quantity of heat. As clearly noted in the reversible chemical formulas, the concentration of CO gas is diluted when Ar gas is added. Thus, the reaction proceeds to the right side (plus direction). As a result, as described above, the decomposition of the raw material gas is promoted. Also, CO gas as a carrier gas is acted in a reverse direction in such a manner that it can inhibit the decomposition of the raw material gas, and thus the reaction proceeds to the left side (reverse direction).

As described above, Ar gas is flowed above wafer W, and the raw material gas (including CO gas) is flowed at the periphery side of wafer W. Thus, the raw material gas is maintained within processing space S for a predetermined time. Furthermore, there is no excess of the raw material gas at the center portion of processing space S, and also the atmosphere in the processing space S is discharged through gas outlet 92. In other words, for processing space S, there is no case in which the concentration of the raw material gas of the center portion is higher than that of the periphery portion. At the same time, the decomposition of the raw material gas is promoted by Ar gas supplied on wafer W, and the film forming speed can be increased to that extent. As a result, it is possible to deposit a Ru film as a thin film at a high film forming speed, while maintaining a high in-plane uniformity of a film thickness. Also, it is possible to promote the decomposition of the raw material gas, and to increase the use efficiency of the raw material gas to that extent.

Herein, for process conditions, the process pressure is in a range from 0.001 to 1 Torr, for example, 0.1 Torr (13.3 Pa), and a wafer temperature is in a range of equal to or higher than a decomposition temperature of the raw material gas, for example, in a range of 150 to 250□, or in a range of about 190 to 230□ in a high temperature state. Also, the flow rate of the raw material gas ranges from 1 to 2 sccm, the flow rate of CO gas as the carrier gas is 100 sccm, and the flow rate of Ar gas as the decomposition promoting gas ranges from about 1 to 200 sccm. Meanwhile, the temperature of shower head 82, inner partition wall 90, and cover ring 76 at the circumferential periphery of placing table 28 is set as a low temperature in a range of lower than a decomposition temperature of the raw material gas, and in a range equal to or higher than a solidifying temperature or a liquidizing temperature of the raw material gas, for example, in a range of 80 to 110□, as described above. Thus, an unnecessary film is not deposited on the surface of these members.

<Action of Ar Gas, and Supply Aspect of Each Gas>

Herein, the action of Ar gas, and supply aspect of each gas will be described. First, based on the above mentioned chemical formulas, Ar gas was used as a decomposition promoting gas of a raw material gas to carry out a verification test. In the test, by using a gas introduction mechanism having a shower head structure, the raw material gas (Ru₃(CO)₁₂) was supplied together with CO gas as a carrier gas during a film forming process, and Ar gas was supplied at the same time. The film forming speed at that time is shown in FIG. 6.

In FIG. 6, the flow rate of Ar gas is changed to 0 sccm, 10 sccm, and 98 sccm, and other process conditions are set to be equal. As shown in FIG. 6, when the flow rate of Ar gas was 0 sccm, a corresponding film thickness was “0.75”. In contrast, when only 10 sccm of Ar gas was added, a corresponding film thickness was slightly increased up to “0.80”. Then, when 98 sccm of Ar gas was added, a corresponding film thickness was significantly increased up to “1.10”.

Accordingly, it can be understood that the addition of Ar gas promotes the decomposition of a raw material gas to that extent, thereby greatly improving a film forming speed. However, the in-plane uniformity of a film thickness may deteriorate by simply adding Ar gas. Thus, an experiment was carried out for this. FIG. 7 is a view schematically showing the result of the experiment. FIG. 7 shows the relationship between a film forming speed on wafer W, and an in-plane uniformity of a film thickness, when a required gas is introduced from a gas introduction mechanism. Herein, except for the supply or no-supply of Ar gas, other process conditions are set to be identical.

FIG. 7(A) shows a result in a supply aspect where only a raw material gas and CO gas (without Ar gas) were flowed by using a shower head as a gas introduction mechanism. In this case, it can be seen that a film forming speed was low, and also the in-plane uniformity of a film thickness was not so high. FIG. 7(B) shows a result in a supply aspect where only a raw material gas and CO gas (without Ar gas) were flowed toward the area further out than the outer peripheral end of wafer W by using a baffle plate as a gas introduction mechanism. This gas supply aspect is the same as that disclosed in Japanese Laid-Open Patent Publication No. 2009-239104. In this case, it can be seen that the in-plane uniformity of a film thickness was sufficiently improved. However, the film forming speed was still insufficient.

FIG. 7(C) shows a result in a supply aspect where a raw material gas including CO gas and Ar gas were flowed in a so-called post-mix by using a shower head as a post-mix type of gas introduction mechanism. In this case, it can be seen that the film forming speed was greatly improved. However, the in-plane uniformity of a film thickness was significantly reduced.

Meanwhile, FIG. 7(D) illustrates the apparatus according to the present disclosure, as described above. Herein, FIG. 7(D) shows a result in a supply aspect where Ar gas was flowed above wafer W, and a raw material gas together with CO gas was flowed at the periphery side of wafer W, as described above. In this case, it can be seen that a film forming speed was greatly improved, and the in-plane uniformity of a film thickness was greatly improved as well.

As described above, according to the present disclosure, the film forming apparatus to form a thin film on a surface of semiconductor wafer W as an object to be processed by using a raw material gas including a raw material of an organometallic compound includes; processing container 22 configured to carry out vacuum exhaustion; placing table 28 including heater 34, on which the object to be processed is disposed; and gas introduction mechanism 80 having a plurality of decomposition promoting gas introduction holes 80A facing placing table 28, and raw material gas introduction holes 80B, wherein decomposition promoting gas introduction holes 80A are disposed while facing the object to be processed on placing table 28 in order to introduce a decomposition promoting gas to promote decomposition of the raw material gas, and raw material gas introduction holes 80B are disposed while surrounding a formation area of the plurality of decomposition promoting gas introduction holes 80A in order to introduce the raw material gas. A decomposition promoting gas is flowed from the decomposition promoting gas introduction holes, and a raw material gas is flowed from the raw material gas introduction holes. Thus, it is possible to improve the in-plane uniformity of a film thickness, and, at the same time, increase the film forming speed as well by improving the reaction efficiency.

### Modified Embodiment 1

Hereinafter, a modified embodiment 1 of the present disclosure will be described. Although, in the above described embodiment, a path area of gas outlet 92 is set to be large to some extent at the lower end side of inner partition wall 90, the present disclosure is not limited thereto. For example, an orifice may be provided in the path area so as to narrow the path area, which prolongs the maintaining time of a raw material gas in processing space S. FIG. 8 is a partial cross-sectional view illustrating modified embodiment 1 of the present disclosure. Also, the same components as those shown in FIG. 2 are designated by the same reference numerals as those in FIG. 2, and their description is omitted.

As shown in FIG. 8, in modified embodiment 1, an orifice forming member 96 is provided at the lower end portion of inner partition wall 90 surrounding the periphery of processing space S. Specifically, at the lower end portion of inner partition wall 90, orifice forming member 96 extends toward the inner side of the end portion along the radial direction of placing table 28, and is formed in a ring shape along the circumferential direction of placing table 28. Also, an orifice 98 communicating with gas outlet 92 is formed between the lower surface of orifice forming member 96 and the circumferential periphery of placing table 28. Accordingly, orifice 98 is partitioned and formed between the lower surface of orifice forming member 96 and the upper surface of cover ring 76 disposed on the circumferential periphery of placing table 28, and is formed in a ring shape along the circumferential direction of placing table 28.

Orifice forming member 96 is made of the same material as that of inner partition wall 90, that is, a satisfactory heat-conductivity material, such as aluminum or aluminum alloy. And, herein, orifice forming member 96 and inner partition wall 90 are integrally molded. In this manner, since orifice forming member 96 extends toward the center of processing container 22, a part of a raw material gas flowed downward from the upper side is flowed toward the center of processing container 22 by a temporary change of flow. Furthermore, the path area of exhausted atmosphere is narrowed by orifice 98, which appropriately prolongs the maintaining time of the raw material gas in processing space S. This improves the film forming speed while maintaining the in-plane uniformity of a film thickness.

Herein, a vertical width L2 of orifice 98 is set as a value ranging from 2 to 19.5 mm. Herein, the width L2 is set as 5 mm, which is the same as that of gas outlet 92. In this case, most of a raw material gas flowed downward into processing space S firstly contacts with orifice forming member 96 extending toward the center of processing space S from the lower end portion of inner partition wall 90, thereby turning toward the center portion of processing space S.

Then, a part of the raw material gas is maintained in processing space S through decomposition promotion by Ar gas, while a large amount of the raw material gas is flowed through orifice 98 with a narrowed path area, and then flowed into the space below placing table 28 via gas outlet 92. Compared to the earlier case of the above described embodiment, modified embodiment 1 can further promote the decomposition of a raw material gas, thereby further improving the film forming speed. Thus, it is possible to further improve the use efficiency of the raw material gas.

Also, although two kinds of gases are supplied from shower head 82 used as gas introduction mechanism 80 in each of the embodiments, the present disclosure is not limited thereto. A shower head for supply of a decomposition promoting gas, and a cover member for covering the entire outside of the shower head at a predetermined gap are provided, and then a raw material gas carried by CO gas as a carrier gas may be flowed and supplied into the gap within the cover member.

Also, although in each of the embodiments, raw material gas introduction holes 80B are provided at the upper side of the area further out than the outer peripheral end of wafer W, the present disclosure is not limited thereto. For example, raw material gas introduction holes 80B may be provided at a position corresponding to the area slightly more inside than the outer peripheral end of wafer W. In other words, raw material gas introduction holes 80B may be positioned at the upper side of the circumferential periphery of wafer W.

Also, although in each of the embodiments, Ar gas is used as a decomposition promoting gas of a raw material gas, the present disclosure is not limited thereto. For example, other noble gases such as He and Ne, or N₂ gas may be used.

Also, in each of the embodiments, as an organometallic compound of a raw material, a material selected from the group consisting Ru₃(CO)₁₂, W(CO)₆, Ni(CO)₄, Mo(CO)₆, CO₂(CO)₈, Rh₄(CO)₁₂, Re₂(CO)₁₀, Cr(CO)₆, OS₃(CO)₁₂, Ta(CO)₅, tetrakis(ethylmethylamino)titanium (TEMAT), TAIMATA, Cu(EDMDD)₂, TaCl₅, trimethyl aluminum (TMA), tertiary-butylimide-tridiethylamide tantalum (TBTDET), pentaethoxy tantalum (PET), tetramethylsilane (TMS), tetrakisethoxy hafnium (TEH), Cp₂Mn[═Mn(C₅H₅)₂], (MeCp)₂Mn[═Mn(CH₃C₅H₄)₂], (EtCp)₂Mn[═Mn(C₂H₅C₅H₄)₂], (i-PrCp)₂Mn[═Mn(C₃H₇C₅H₄)₂], MeCpMn(CO)₃[═(CH₃C₅H₄)Mn(CO)₃], (t-BuCp)₂Mn[═Mn(C₄H₉C₅H₄)₂], CH₃Mn(CO)₅, Mn(DPM)₃[=Mn(C₁₁H₁₉O₂)₃], Mn(DMPD)(EtCp)[=Mn(C₇H₁₁C₂H₅C₅H₄)], Mn(acac)₂[=Mn(C₅H₇O₂)₂], and Mn(DPM)₂[=Mn(C₁₁H₁₉O₂)₂], Mn(acac)₃[=Mn(C₅H₇O₂)₃] may be used.

Also, in the above description, a semiconductor wafer is used as an object to be processed. The semiconductor wafer may include a silicon substrate, and a compound semiconductor substrate such as GaAs, SiC, GaN, etc. However, the present disclosure is not limited to the above substrates, and may be applied to other type of substrates such as a glass substrate or a ceramic substrate, used for a liquid crystal display device.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A film forming apparatus to form a thin film on a surface of an object to be processed by using a raw material gas comprising a raw material of an organometallic compound, the film forming apparatus comprising:
a processing container configured to carry out vacuum exhaustion;
a placing table having a heater configured to dispose the object to be processed thereon; and
a gas introduction mechanism having a plurality of decomposition promoting gas introduction holes facing the placing table, and raw material gas introduction holes, wherein the decomposition promoting gas introduction holes being disposed while facing the object to be processed on the placing table in order to introduce a decomposition promoting gas to promote decomposition of the raw material gas, and the raw material gas introduction holes being disposed while surrounding a formation area of the plurality of decomposition promoting gas introduction holes in order to introduce the raw material gas.

2. The film forming apparatus as claimed in claim 1, wherein the decomposition promoting gas introduction holes are disposed at a position corresponding to an upper side in a perpendicular direction of the object to be processed on the placing table, and the raw material gas introduction holes are disposed at a position corresponding to an upper side in a perpendicular direction of an area further out than an outer peripheral end of the object to be processed on the placing table.

3. The film forming apparatus as claimed in claim 1, wherein the processing container has an inner partition wall within the processing container, wherein the inner partition wall partitions a processing space at an upper side of the placing table in such a manner that the inner partition wall surrounds the processing space, a lower end portion of the inner partition wall is provided in such a manner that the lower end portion approaches the placing table, and a gas outlet is formed between the lower portion and a circumferential periphery of the placing table.

4. The film forming apparatus as claimed in claim 2, wherein the processing container has an inner partition wall within the processing container, wherein the inner partition wall partitions a processing space at an upper side of the placing table in such a manner that the inner partition wall surrounds the processing space, a lower end portion of the inner partition wall is provided in such a manner that the lower end portion approaches the placing table, and a gas outlet is formed between the lower portion and a circumferential periphery of the placing table.

5. The film forming apparatus as claimed in claim 3, wherein an orifice forming member is provided at the lower end portion of the inner partition wall, the orifice forming member extends toward an inner side along a radial direction of the placing table, and an orifice communicating with the gas outlet is formed between the orifice forming member and the circumferential periphery of the placing table.

6. The film forming apparatus as claimed in claim 5, wherein the inner partition wall and the orifice forming member are maintained at a temperature range lower than a decomposition temperature of the raw material gas, and maintained equal to or higher than a solidifying temperature or a liquidizing temperature of the raw material gas.

7. The film forming apparatus as claimed in claim 1, wherein the placing table is configured to be moved up and down.

8. The film forming apparatus as claimed in claim 2, wherein the placing table is configured to be moved up and down.

9. The film forming apparatus as claimed in claim 1, wherein the organometallic compound comprises one material selected from the group consisting Ru₃(CO)₁₂, W(CO)₆, Ni(CO)₄, Mo(CO)₆, CO₂(CO)₈, Rh₄(CO)₁₂, Re₂(CO)₁₀, Cr(CO)₆, Os₃(CO)₁₂, Ta(CO)₅, tetrakis(ethylmethylamino)titanium (TEMAT), TAIMATA, Cu(EDMDD)₂, TaCl₅, trimethyl aluminum (TMA), tertiary-butylimide-tridiethylamide tantalum (TBTDET), pentaethoxy tantalum (PET), tetramethylsilane (TMS), tetrakisethoxy hafnium (TEH), Cp₂Mn[═Mn(C₅H₅)₂], (MeCp)₂Mn[═Mn(CH₃C₅H₄)₂], (EtCp)₂Mn[═Mn(C₂H₅C₅H₄)₂], (i-PrCp)₂Mn[═Mn(C₃H₇C₅H₄)₂], MeCpMn(CO)₃[═(CH₃C₅H₄)Mn(CO)₃], (t-BuCp)₂Mn[═Mn(C₄H₉C₅H₄)₂], CH₃Mn(CO)₅, Mn(DPM)₃[=Mn(C₁₁H₁₉O₂)₃], Mn(DMPD)(EtCp)[=Mn(C₇H₁₁C₂H₅C₅H₄)], Mn(acac)₂[=Mn(C₅H₇O₂)₂], Mn(DPM)₂[=Mn(C₁₁H₁₉O₂)₂], and Mn(acac)₃[=Mn(C₅H₇O₂)₃].

10. The film forming apparatus as claimed in claim 2, wherein the organometallic compound comprises one material selected from the group consisting Ru₃(CO)₁₂, W(CO)₆, Ni(CO)₄, Mo(CO)₆, CO₂(CO)₈, Rh₄(CO)₁₂, Re₂(CO)₁₀, Cr(CO)₆, Os₃(CO)₁₂, Ta(CO)₅, tetrakis(ethylmethylamino)titanium (TEMAT), TAIMATA, Cu(EDMDD)₂, TaCl₅, trimethyl aluminum (TMA), tertiary-butylimide-tridiethylamide tantalum (TBTDET), pentaethoxy tantalum (PET), tetramethylsilane (TMS), tetrakisethoxy hafnium (TEH), Cp₂Mn[═Mn(C₅H₅)₂], (MeCP)₂Mn[═Mn(CH₃C₅H₄)₂], (EtCp)₂Mn[═Mn(C₂H₅C₅H₄)₂], (i-PrCp)₂Mn[═Mn(C₃H₇C₅H₄)₂], MeCpMn(CO)₃[═CH₃C₅H₄)Mn(CO)₃], (t-BuCp)₂Mn[═Mn(C₄H₉C₅H₄)₂], CH₃Mn(CO)₅, Mn(DPM)₃[=Mn(C₁₁H₁₉O₂)₃], Mn(DMPD)(EtCp)[=Mn(C₇H₁₁C₂H₅C₅H₄)], Mn(acac)₂[=Mn(C₅H₇O₂)₂], Mn(DPM)₂[=Mn(C₁₁H₁₉O₂)₂], and Mn(acac)₃[=Mn(C₅H₇O₂)₃].
